(19) United States
(12) Patent Application Publication
(10) Pub. No.: US 2022/0254956 A1
(43) Pub. Date: Aug. 11, 2022

(54) EPITAXIAL STRUCTURE, LIGHT EMITTING DEVICE, AND METHOD FOR EPITAXIAL STRUCTURE MANUFACTURE

(71) Applicant: CHONGQING KONKA PHOTOELECTRIC TECHNOLOGY RESEARCH INSTITUTE CO., LTD., Chongqing (CN)

(72) Inventors: Shun-kuei YANG, Chongqing (CN); Yi ZHOU, Chongqing (CN)

(21) Appl. No.: 17/576,273

(22) Filed: Jan. 14, 2022

Related U.S. Application Data
(63) Continuation of application No. PCT/CN2021/076529, filed on Feb. 10, 2021.

(51) Int. Cl. H01L 33/12; H01L 33/32; H01L 33/00

(52) U.S. Cl. CPC H01L 33/12; H01L 33/007; H01L 33/32

(57) ABSTRACT

An epitaxial structure, a light emitting device, and a method for epitaxial structure manufacture are provided. The epitaxial structure includes a buffer layer and a stress releasing layer that are sequentially formed on a substrate. The stress releasing layer includes a first stress releasing layer. The first stress releasing layer is made of aluminum gallium nitride (AlGaN) in which Al component accounts for 50%-90%.

### CROSS-REFERENCE TO RELATED APPLICATIONS

This application is a continuation of International Application No. PCT/CN2021/076529, filed on Feb. 10, 2021 the entire disclosure of which is incorporated herein by reference.

### TECHNICAL FIELD

The disclosure relates to the field of semiconductor light emitting technology, and more particularly to an epitaxial structure, a light emitting device, and a method for epitaxial structure manufacture.

### BACKGROUND

In order to promote commercialization of a micro-light emitting diode (micro-LED), introduction of a large-size epitaxial substrate to reduce a cost is imperative. However, there are significant lattice mismatch and thermal mismatch between a preferred large-size substrate (silicon substrate or sapphire substrate) and a main material gallium nitride (GaN) of an epitaxial layer. Warpage caused by lattice thermal mismatch becomes more obvious after the size of the substrate is increased, and a warpage variation directly affects uniformity of an epitaxial structure. To solve this problem, it is necessary to introduce a more reasonable stress releasing layer in a bottom layer to offset the warpage caused by lattice thermal mismatch. Therefore, it is imperative to achieve high-efficiency development of a micro-LED product with cooperation of an advanced stress releasing layer and a large-size substrate.

Compared with a large-size device, it is more difficult for a micro-light emitting diode (micro-LED) to separate light and color, and wavelength uniformity of the micro-LED directly affects a color accuracy of display, so it is necessary to put forward a higher requirement for the wavelength uniformity of the micro-LED. Based on considerations of technological progress and process cost, an epitaxial substrate of the micro-LED is continuously developing in a direction of large size. The larger the size of the substrate, the more difficult it is to control a stress during a growth process of an epitaxial structure, and thus the more difficult it is to control the wavelength uniformity.

Therefore, how to control a stress level of the epitaxial structure in the case of a larger-size substrate and then the wavelength uniformity is a problem to be solved.

### SUMMARY

In a first aspect, an epitaxial structure includes a substrate, a buffer layer formed on the substrate, and a stress releasing layer. The stress releasing layer includes a first stress releasing layer formed on the buffer layer, and the first stress releasing layer is made of aluminum gallium nitride (AlGaN) in which Al component accounts for 50%-90%.

In a second aspect, a light emitting device is further provided in the disclosure. The light emitting device includes the epitaxial structure in any of the foregoing implementations.

In a third aspect, a method for epitaxial structure manufacture is further provided in the disclosure. The method includes the following. A buffer layer is formed on a substrate. A stress releasing layer is formed on the buffer layer. The stress releasing layer includes a first stress releasing layer formed on the buffer layer, and the first stress releasing layer is made of AlGaN in which Al component accounts for 50%-90%.

### BRIEF DESCRIPTION OF THE DRAWINGS

FIG. 1 is a schematic structural diagram illustrating an epitaxial structure in an implementation.

Description of reference signs of the accompanying drawings: 10—substrate; 20—buffer layer; 30—first stress releasing layer (i.e., stress releasing layer A); 40—second stress releasing layer (i.e., stress releasing layer B); 50—third stress releasing layer (i.e., stress releasing layer C); 51—first sub-stress releasing layer; 52—second sub-stress releasing layer; 60—fourth stress releasing layer (i.e., stress releasing layer D); 70—N-type gallium nitride (GaN) layer; 80—multi-quantum well (MQW) light emitting layer; 90—P-type GaN layer.

### DETAILED DESCRIPTION

A display panel and a splicing display apparatus are provided in the disclosure. In order to make the purposes, technical solutions, and advantages of the present disclosure clearer, the following will describe the present disclosure in detail with combination of accompanying drawings and implementations. It should be understood that, implementations described herein are merely for explaining, rather than limiting, the present disclosure.

In description of the disclosure, it should be understood that locations or positional relationships indicated by terms such as “center”, “lateral”, “on”, “under”, “left”, “right”, “vertical”, “horizontal”, “top”, “bottom”, “in”, “out”, and the like are locations or positional relationship based on accompanying drawings and are only for the convenience of description and simplicity, rather than explicitly or implicitly indicate that apparatuses or components referred to herein must have a certain direction or be configured or operated in a certain direction and therefore cannot be understood as limitations to the disclosure. In addition, terms “first”, “second”, and the like are only used for description and cannot be understood as explicitly or implicitly indicating relative importance or implicitly indicating the number of technical features referred to herein. Therefore, features limited by terms “first”, “second”, and the like can explicitly or implicitly include at least one of the features. In the context of the present disclosure, unless stated otherwise, “multiple” or “a plurality of” refers to “at least two”. In addition, the terms “include”, “comprise”, and “have” as well as variations thereof are intended to cover non-exclusive inclusion.

In description of the present disclosure, it should be noted that, unless stated otherwise, terms “installing”, “coupling”, and “connecting” referred to herein should be understood in broader sense. For example, they may include a fixed coupling, a removable coupling, or an integrated coupling; they may include a mechanical coupling or an electrical coupling; they may include a direct coupling, an indirect coupling through a medium, or an interconnection between two components or an interaction coupling between two components. For those of ordinary skill in the art, the above terms in the present disclosure can be understood according to specific situations.

The terms used herein are merely illustrative of exemplary implementations only for the specific implementations. Unless the context clearly refers to, the singular forms “a” and “an” used herein are also intended to include the plural. It should also be understood that the terms “including” and/or “comprising” as specifying the features, integers, steps, operations, units, and/or components are presented herein, without excluding presence or add one or more other features, integers, steps, operations, units, components, and/or combinations thereof.

Crystal quality of an epitaxial structure of a micro-light emitting diode (micro-LED) can directly affect a display effect. Compared with a large-size LED chip, the micro-LED has more significant problems in epitaxial structure defect, polarized electric field influence, and wavelength uniformity. Since a micro-LED chip has a size less than 50 microns (um), the micro-LED chip is at low current density when applied to display, so non-radiative recombination caused by a surface defect becomes particularly important. Moreover, statistical fluctuation of threading dislocation density between chips on the same epitaxial structure is more significant due to size reduction, so an epitaxial structure with lower defect density is needed for the micro-LED or these defect structures are passivated. A polarized electric field in an active area of the micro-LED may lead to separation of electron and hole wave functions, thereby reducing internal quantum efficiency. The polarized electric field may make a peak wavelength of light emission deviate when the current density changes, which is not conducive to display applications. Therefore, it is necessary to effectively control the polarized electric field in the active area.

Compared with a large-size device, it is more difficult for the micro-LED to separate light and color, and the wavelength uniformity of the micro-LED directly affects a color accuracy of display, so it is necessary to put forward a higher requirement for the wavelength uniformity of the micro-LED. Based on considerations of technological progress and process cost, the epitaxial substrate of the micro-LED is continuously developing in a direction of large size. The larger the size of the substrate, the more difficult it is to control a stress during a growth process of an epitaxial structure, and thus the more difficult it is to control the wavelength uniformity.

Therefore, how to control a stress level of the epitaxial structure in the case of a larger-size substrate and then the wavelength uniformity is a problem to be solved.

Considering disadvantages of the above-mentioned related art, in this disclosure, an epitaxial structure, a light emitting device, and a method for epitaxial structure manufacture are provided, which is possible to control a stress level of the epitaxial structure in the case of a larger-size substrate and then wavelength uniformity.

An epitaxial structure includes a substrate, a buffer layer formed on the substrate, and a stress releasing layer. The stress releasing layer includes a first stress releasing layer formed on the buffer layer, and the first stress releasing layer is made of aluminum gallium nitride (AlGaN) in which Al component accounts for 50%-90%.

The first stress releasing layer is made of AlGaN with higher Al content, such that compressive stress can be introduced in advance, thereby achieving epitaxial growth of a high-quality and crack-free gallium nitride (GaN) thin film. Based on the transmission electron microscope (TEM) representation and the Hall test method, not only does the first stress releasing layer with high Al content filter a large amount of dislocations, but also the introduced compressive stress makes a part of the large amount of dislocations disappear, and finally a crack-free GaN thin film with a smooth mirror surface and low dislocation density is realized. Compared with a structure without the stress releasing layer, the epitaxial structure in the disclosure reduces a surface roughness of the thin film by 20%-50% and reduces the dislocation density by 30%-50%, thereby controlling the stress level of the epitaxial structure in the case of a larger-size substrate and then the wavelength uniformity.

In an implementation, the stress releasing layer further includes a second stress releasing layer formed on the first stress releasing layer and a fourth stress releasing layer formed on the second stress releasing layer. The second stress releasing layer is made of aluminum nitride (AlN) and has a quality ratio of group V (N) element to group III (Al) element (V/III ratio) of 400-1000, and the fourth stress releasing layer is made of AlN and has a V/III ratio of 30-100.

A higher V/III ratio can change a growth manner of the second stress releasing layer, making the second stress releasing layer more inclined to a three-dimensional (3D) growth mode. A high V/III ratio represents that crystal quality is further improved and defect density is further reduced, and finally internal quantum efficiency is significantly improved. The fourth stress releasing layer with a lower V/III ratio is more inclined to a two-dimensional (2D) growth mode and has a smooth surface that provides a basis for high-quality growth of a subsequent layer.

In an implementation, the stress releasing layer further includes a third stress releasing layer formed on the first stress releasing layer. The third stress releasing layer is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, and the second sub-stress releasing layer is made of GaN.

In an implementation, the stress releasing layer further includes a second stress releasing layer formed on the first stress releasing layer, a third stress releasing layer formed on the second stress releasing layer, and a fourth stress releasing layer formed on the third stress releasing layer. The second stress releasing layer is made of AlN and has a V/III ratio of 400-1000. The third stress releasing layer is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, the second sub-stress releasing layer is made of GaN. The fourth stress releasing layer is made of AlN and has a V/III ratio of 30-100.

Combining the first stress releasing layer to the fourth stress releasing layer above, on the one hand, the epitaxial structure in the implementation alleviates excessive tensile stress caused by lattice mismatch and thermal mismatch between a large-size substrate and the epitaxial structure and solves a problem of a crack of the epitaxial structure grown on the large-size substrate, especially a silicon substrate, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the quantum confined stark effect (QCSE) caused by piezoelectric polarization in a multi-quantum light emitting layer can be reduced, thereby realizing efficient combination of electrons and holes in a quantum well, and thus significantly improving light emitting efficiency.

In an implementation, the first stress releasing layer has a thickness within 50-150 nanometers (nm). Through setting the first stress releasing layer with the thickness of the implementation, a reasonable thickness can reduce the defect density caused by lattice mismatch, thereby improving the crystal quality of the epitaxial structure, and thus improving the light emitting efficiency.

In an implementation, the second stress releasing layer has a thickness within 50-100 nm. Through setting the second stress releasing layer with the thickness of the implementation, a reasonable thickness can reduce the defect density caused by lattice mismatch, thereby improving the crystal quality of the epitaxial structure, and thus improving the light emitting efficiency.

In an implementation, the first sub-stress releasing layer in the third stress releasing layer has a thickness less than 10 nm, and the second sub-stress releasing layer in the third stress releasing layer has a thickness within 15-30 nm. Through setting the third stress releasing layer with the thickness of the implementation, a reasonable thickness can reduce the defect density caused by lattice mismatch, thereby improving the crystal quality of the epitaxial structure, and thus improving the light emitting efficiency.

In an implementation, the fourth stress releasing layer has a thickness within 20-50 nm. Through setting the fourth stress releasing layer with the thickness of the implementation, a reasonable thickness can reduce the defect density caused by lattice mismatch, thereby improving the crystal quality of the epitaxial structure, and thus improving the light emitting efficiency.

In an implementation, the epitaxial structure further includes an N-type GaN layer, a multi-quantum well (MQW) light emitting layer, and a P-type GaN layer that are sequentially formed on the stress releasing layer.

Based on the same concept, a light emitting device is further provided in the disclosure. The light emitting device includes the epitaxial structure in any of the foregoing implementations.

Based on the same concept, a method for epitaxial structure manufacture is further provided in the disclosure. The method includes the following. A buffer layer is formed on a substrate. A stress releasing layer is formed on the buffer layer. The stress releasing layer includes a first stress releasing layer formed on the buffer layer, and the first stress releasing layer is made of AlGaN in which Al component accounts for 50%-90%.

The first stress releasing layer is made of AlGaN with higher Al content, such that compressive stress can be introduced in advance, thereby achieving epitaxial growth of a high-quality and crack-free GaN thin film. Based on the TEM representation and the Hall test method, not only does the first stress releasing layer with high Al content filter a large amount of dislocations, but also the introduced compressive stress makes a part of the large amount of dislocations disappear, and finally a crack-free GaN thin film with a smooth mirror surface and low dislocation density is realized. Compared with a structure without the stress releasing layer, the epitaxial structure in the disclosure reduces a surface roughness of the thin film by 20%-50% and reduces the dislocation density by 30%-50%, thereby controlling the stress level of the epitaxial structure in the case of a larger-size substrate and then the wavelength uniformity.

In an implementation, the stress releasing layer further includes a second stress releasing layer and a fourth stress releasing layer, and the method further includes the following. The second stress releasing layer is formed on the first stress releasing layer, and the fourth stress releasing layer is formed on the second stress releasing layer. The second stress releasing layer is made of AlN and has a V/III ratio of 400-1000, and the fourth stress releasing layer is made of AlN and has a V/III ratio of 30-100.

A higher V/III ratio can change a growth manner of the second stress releasing layer, making the second stress releasing layer more inclined to a 3D growth mode. A high V/III ratio represents that the crystal quality is further improved and the defect density is further reduced, and finally the internal quantum efficiency is significantly improved. The fourth stress releasing layer with a lower V/III ratio is more inclined to a 2D growth mode and has a smooth surface that provides a basis for high-quality growth of a subsequent layer.

In an implementation, the stress releasing layer further includes a third stress releasing layer, and the method further includes the following. The third stress releasing layer is formed on the first stress releasing layer. The third stress releasing layer is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, and the second sub-stress releasing layer is made of GaN.

Through setting the third stress releasing layer in the implementation, the first sub-stress releasing layer and the second sub-stress releasing layer under larger compressive strain further decrease the tensile stress caused by lattice mismatch and thermal mismatch, reduce an electric field of the piezoelectric polarization of the MQW light emitting layer, thereby weakening the QCSE, and thus improving radiative recombination efficiency of electrons and holes.

In an implementation, the stress releasing layer further includes a second stress releasing layer, a third stress releasing layer, and a fourth stress releasing layer, and the method further includes the following. The second stress releasing layer is formed on the first stress releasing layer, the third stress releasing layer is formed on the second stress releasing layer, and the fourth stress releasing layer is formed on the third stress releasing layer. The second stress releasing layer is made of AlN and has a V/III ratio of 400-1000. The third stress releasing layer is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, and the second sub-stress releasing layer is made of GaN. The fourth is made of AlN and has a V/III ratio of 30-100.

Combining the first stress releasing layer to the fourth stress releasing layer above, on the one hand, the epitaxial structure in the implementation alleviates excessive tensile stress caused by lattice mismatch and thermal mismatch between a large-size substrate and the epitaxial structure and solves a problem of a crack of the epitaxial structure grown on the large-size substrate, especially a silicon substrate, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the QCSE caused by the piezoelectric polarization in the multi-quantum light emitting layer can be reduced, thereby realizing efficient combination of electrons and holes in the quantum well, and thus significantly improving the light emitting efficiency.

In an implementation, the first stress releasing layer is formed under a condition that a temperature is greater than 1000° C. and a pressure is less than 75 millibar (mbar), and the first stress releasing layer has a thickness within 50-150 nm. Through setting the temperature and the pressure condition of the implementation and generating the first stress releasing layer with the thickness of the implementation, on the one hand, excessive tensile stress caused by lattice mismatch and thermal mismatch between a large-size substrate and the epitaxial structure is reasonably alleviated, a problem of a crack of the epitaxial structure grown on the large-size substrate, especially a silicon substrate, is solved, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the QCSE caused by the piezoelectric polarization in the MQW light emitting layer can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

In an implementation, the second stress releasing layer is formed under a condition that a temperature is greater than 1050° C. and a pressure is less than 75 mbar, and the second stress releasing layer has a thickness within 50-100 nm. Through setting the temperature and the pressure condition of the implementation and generating the second stress releasing layer with the thickness of the implementation, on the one hand, excessive tensile stress caused by lattice mismatch and thermal mismatch between a large-size substrate and the epitaxial structure is reasonably alleviated, a problem of a crack of the epitaxial structure grown on the large-size substrate, especially a silicon substrate, is solved, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the QCSE caused by the piezoelectric polarization in the MQW light emitting layer can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

In an implementation, the third stress releasing layer is formed under a condition that a temperature is greater than 1000° C. and a pressure is less than 200 mbar, and the first sub-stress releasing layer in the third stress releasing layer has a thickness less than 10 nm, and the second sub-stress releasing layer in the third stress releasing layer has a thickness within 15-30 nm. Through setting the temperature and the pressure condition of the implementation and generating the third stress releasing layer with the thickness of the implementation, on the one hand, excessive tensile stress caused by lattice mismatch and thermal mismatch between a large-size substrate and the epitaxial structure is reasonably alleviated, a problem of a crack of the epitaxial structure grown on the large-size substrate, especially a silicon substrate, is solved, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the QCSE caused by the piezoelectric polarization in the MQW light emitting layer can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

In an implementation, the fourth stress releasing layer is formed under a condition that a temperature is greater than 1050° C. and a pressure is less than 75 mbar, and the fourth stress releasing layer has a thickness within 20-50 nm. Through setting the temperature and the pressure condition of the implementation and generating the fourth stress releasing layer with the thickness of the implementation, on the one hand, excessive tensile stress caused by lattice mismatch and thermal mismatch between a large-size substrate and the epitaxial structure is reasonably alleviated, a problem of a crack of the epitaxial structure grown on the large-size substrate, especially a silicon substrate, is solved, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the QCSE caused by the piezoelectric polarization in the MQW light emitting layer can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

In an implementation, the method further includes the following. An N-type GaN layer, a MQW light emitting layer, and a P-type GaN layer are formed sequentially on the stress releasing layer.

Through setting the third stress releasing layer in the implementation, the first sub-stress releasing layer and the second sub-stress releasing layer under larger compressive strain further decrease the tensile stress caused by lattice mismatch and thermal mismatch, reduce an electric field of the piezoelectric polarization of the multi-quantum light emitting layer, thereby weakening the quantum confined stark effect (QCSE), and thus improving radiative recombination efficiency of electrons and holes.

Based on the above, a solution for solving the technical problems above is provided in the disclosure, which will be explained in detail in the following implementations.

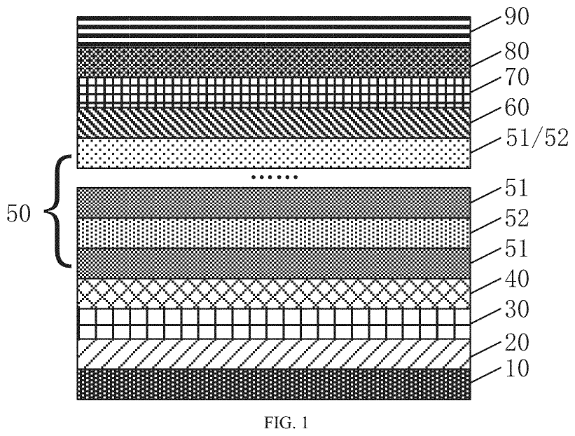

Referring to FIG. 1, an epitaxial structure is provided in implementations of the disclosure. The epitaxial structure includes a substrate 10, a buffer layer 20, and a stress releasing layer.

The substrate 10 may be a large-size substrate (not smaller than 6 inches) and made of silicon.

The buffer layer 20 is formed on the substrate 10, and the stress releasing layer is formed on the buffer layer 20.

The epitaxial structure further includes an N-type gallium nitride (GaN) layer 70, a multi-quantum well (MQW) light emitting layer 80, and a P-type GaN layer 90 that are sequentially formed on the stress releasing layer.

Implementation one: The stress releasing layer includes a first stress releasing layer 30, a second stress releasing layer 40, a third stress releasing layer 50, and a fourth stress releasing layer 60. The first stress releasing layer 30 is formed on the buffer layer 20. The second stress releasing layer 40 is formed on the first stress releasing layer 30. The third stress releasing layer 50 is formed on the second stress releasing layer 40. The fourth stress releasing layer 60 is formed on the third stress releasing layer 50. The N-type GaN layer 70 is formed on the fourth stress releasing layer 60.

The first stress releasing layer 30 is made of aluminum gallium nitride (AlGaN) in which Al component accounts for 50%-90%. Alternatively, the content of Al component may be 50%, 60%, 70%, 80%, 90%, or the like, preferably 75%.

The first stress releasing layer 30 is made of AlGaN with higher Al content, such that compressive stress can be introduced in advance, thereby achieving epitaxial growth of a high-quality and crack-free GaN thin film. Based on the transmission electron microscope (TEM) representation and the Hall test method, not only does the first stress releasing layer 30 with high Al content filter a large amount of dislocations, but also the introduced compressive stress makes a part of the large amount of dislocations disappear, and finally a crack-free GaN thin film with a smooth mirror surface and low dislocation density is realized. Compared with a structure without the stress releasing layer, the epitaxial structure in the disclosure reduces a surface roughness of the thin film by 20%-50% and reduces the dislocation density by 30%-50%, thereby controlling the stress level of the epitaxial structure in the case of a larger-size substrate 10 and then the wavelength uniformity.

When the first stress releasing layer 30 is manufactured, the first stress releasing layer 30 is grown on the buffer layer 20 under a condition that a temperature is greater than 1000° C. and a pressure is less than 75 millibar (mbar), and the first stress releasing layer 30 has a thickness within 50-150 nm. Alternatively, the temperature may be 1020° C., 1040° C., 1050° C., 1060° C., 1080° C., 1100° C., or the like, preferably 1050° C. Alternatively, the pressure may be 40 mbar, 45 mbar, 50 mbar, 55 mbar, 60 mbar, 65 mbar, 70 mbar, or the like, preferably 50 mbar. Alternatively, the thickness may be 50 nm, 80 nm, 100 nm, 120 nm, 130 nm, 140 nm, 150 nm, or the like, preferably 120 nm.

Through setting the temperature and the pressure condition of the implementation and generating the first stress releasing layer 30 with the thickness of the implementation, on the one hand, excessive tensile stress caused by lattice mismatch and thermal mismatch between a large-size substrate 10 and the epitaxial structure is reasonably alleviated, a problem of a crack of the epitaxial structure grown on the large-size substrate 10, especially a silicon substrate, is solved, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the quantum confined stark effect (QCSE) caused by the piezoelectric polarization in the MQW light emitting layer 80 can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

The second stress releasing layer 40 is made of aluminum nitride (AlN) and has a quality ratio of group V (N) element to group III (Al) element (V/III ratio) of 400-1000. Alternatively, the V/III ratio may be 400, 500, 600, 700, 800, 900, 1000, or the like, preferably 600. The V/III ratio refers to a quality ratio of group V element to group III element in a periodic table of elements in a chemical compound.

A higher V/III ratio can change a growth manner of the second stress releasing layer 40, making the second stress releasing layer 40 more inclined to a three-dimensional (3D) growth mode. A high V/III ratio represents that the crystal quality is further improved and the defect density is further reduced, and finally the internal quantum efficiency is significantly improved.

When the second stress releasing layer 40 is manufactured, the second stress releasing layer 40 is formed under a condition that a temperature is greater than 1050° C. and a pressure is less than 75 mbar, and the second stress releasing layer 40 has a thickness within 50-100 nm. Alternatively, the temperature may be 1060° C., 1080° C., 1100° C., 1120° C., 1140° C., 1150° C., or the like, preferably 1100° C. Alternatively, the pressure may be 40 mbar, 45 mbar, 50 mbar, 55 mbar, 60 mbar, 65 mbar, 70 mbar, or the like, preferably 50 mbar. Alternatively, the thickness may be 50 nm, 60 nm, 70 nm, 80 nm, 90 nm, 100 nm, or the like, preferably 80 nm.

Through setting the temperature and the pressure condition of the implementation and generating the second stress releasing layer 40 with the thickness of the implementation, on the one hand, excessive tensile stress caused by lattice mismatch and thermal mismatch between a large-size substrate 10 and the epitaxial structure is reasonably alleviated, a problem of a crack of the epitaxial structure grown on the large-size substrate 10, especially a silicon substrate, is solved, thereby improving the crystal quality, also improving the uniformity of the micro-LED caused by stress under the large-size substrate after the stress is effectively controlled, and correspondingly reducing color difference caused by inconsistent emission wavelengths of a micro-LED chip. On the other hand, the QCSE caused by the piezoelectric polarization in the MQW light emitting layer 80 can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

The third stress releasing layer 50 is a super-lattice structure formed by alternate growth of a first sub-stress releasing layer 51 and a second sub-stress releasing layer 52. The alternate growth starts from the first sub-stress releasing layer 51 and has an alternate growth period not greater than 100. The first sub-stress releasing layer 51 is made of AlN, and the second sub-stress releasing layer 52 is made of GaN. As illustrated in FIG. 1, the first sub-stress releasing layer 51 is grown on the second stress releasing layer 40, the second sub-stress releasing layer 52 is grown on the first sub-stress releasing layer 51, and a next first sub-stress releasing layer 51 is grown on the second sub-stress releasing layer 52. According to the above, the alternate growth is conducted until an n-th first sub-stress releasing layer 51 or second sub-stress releasing layer 52 is grown, and n is not greater than 200, i.e., every growth of the first sub-stress releasing layer 51 and the second sub-stress releasing layer 52 is regarded as a period.

Through setting the third stress releasing layer 50 in the implementation, the first sub-stress releasing layer 51 and the second sub-stress releasing layer 52 under larger compressive strain further decrease the tensile stress caused by lattice mismatch and thermal mismatch, reduce an electric field of the piezoelectric polarization of the MQW light emitting layer 80, thereby weakening the QCSE, and thus improving radiative recombination efficiency of electrons and holes.

When the third stress releasing layer 50 is manufactured, the third stress releasing layer 50 is formed under a condition that a temperature is greater than 1000° C. and a pressure is less than 200 mbar, and the first sub-stress releasing layer 51 in the third stress releasing layer 50 has a thickness less than 10 nm, and the second sub-stress releasing layer 52 in the third stress releasing layer 50 has a thickness within 15-30 nm.

Alternatively, the temperature may be 1020° C., 1040° C., 1050° C., 1060° C., 1080° C., 1100° C., or the like, preferably 1050° C. Alternatively, the pressure may be 50 mbar, 80 mbar, 100 mbar, 120 mbar, 150 mbar, 180 mbar, 200 mbar, or the like, preferably 100 mbar. Alternatively, the thickness of the first sub-stress releasing layer 51 may be 2 nm, 4 nm, 5 nm, 6 nm, 8 nm, 9 nm, or the like, preferably 5 nm. Alternatively, the thickness of the second sub-stress releasing layer 52 may be 15 nm, 18 nm, 20 nm, 22 nm, 25 nm, 28 nm, 30 nm, or the like, preferably 22 nm.

Through setting the temperature and the pressure condition of the implementation and generating the third stress releasing layer 50 with the thickness of the implementation, on the one hand, excessive tensile stress caused by lattice mismatch and thermal mismatch between a large-size substrate 10 and the epitaxial structure is reasonably alleviated, a problem of a crack of the epitaxial structure grown on the large-size substrate 10, especially a silicon substrate, is solved, thereby improving the crystal quality, also improving the uniformity of the micro-LED caused by stress under the large-size substrate 10 after the stress is effectively controlled, and correspondingly reducing color difference caused by inconsistent emission wavelengths of a micro-LED chip. On the other hand, the QCSE caused by the piezoelectric polarization in the MQW light emitting layer 80 can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

The fourth stress releasing layer 60 is made of AlN and has a V/III ratio of 30-100. Alternatively, the V/III ratio may be 30, 40, 50, 60, 70, 80, 90, 100, or the like, preferably 50.

The fourth stress releasing layer 60 with a lower V/III ratio is more inclined to a 2D growth mode and has a smooth surface that provides a basis for high-quality growth of a subsequent layer.

When the fourth stress releasing layer 60 is manufactured, the fourth stress releasing layer 60 is formed under a condition that a temperature is greater than 1050° C. and a pressure is less than 75 mbar, and the fourth stress releasing layer 60 has a thickness within 20-50 nm. Alternatively, the temperature may be 1060° C., 1080° C., 1100° C., 1120° C., 1140° C., 1150° C., or the like, preferably 1100° C. Alternatively, the pressure may be 40 mbar, 45 mbar, 50 mbar, 55 mbar, 60 mbar, 65 mbar, 70 mbar, or the like, preferably 50 mbar. Alternatively, the thickness may be 20 nm, 30 nm, 35 nm, 40 nm, 50 nm, or the like, preferably 35 nm.

Through setting the temperature and the pressure condition of the implementation and generating the fourth stress releasing layer 60 with the thickness of the implementation, on the one hand, excessive tensile stress caused by lattice mismatch and thermal mismatch between a large-size substrate 10 and the epitaxial structure is reasonably alleviated, a problem of a crack of the epitaxial structure grown on the large-size substrate 10, especially a silicon substrate, is solved, thereby improving the crystal quality, also improving the uniformity of the micro-LED caused by stress under the large-size substrate 10 after the stress is effectively controlled, and correspondingly reducing color difference caused by inconsistent emission wavelengths of a micro-LED chip. On the other hand, the QCSE caused by the piezoelectric polarization in the MQW light emitting layer 80 can be reduced, thereby realizing efficient combination of electrons and holes in the quantum well, and thus significantly improving the light emitting efficiency. A reasonable thickness can reduce the defect density caused by lattice mismatch, thereby improving the crystal quality of the epitaxial structure, and thus improving the light emitting efficiency.

Combining the first stress releasing layer 30 to the fourth stress releasing layer 60 above, on the one hand, the epitaxial structure in the implementation alleviates excessive tensile stress caused by lattice mismatch and thermal mismatch between the large-size substrate 10 and the epitaxial structure and solves a problem of a crack of the epitaxial structure grown on the large-size substrate 10, especially a silicon substrate 10, thereby improving the crystal quality, also improving the uniformity of the micro-LED caused by stress under the large-size substrate 10 after the stress is effectively controlled, and correspondingly reducing color difference caused by inconsistent emission wavelengths of a micro-LED chip. On the other hand, the QCSE caused by the piezoelectric polarization in the multi-quantum light emitting layer can be reduced, thereby realizing efficient combination of electrons and holes in the quantum well, and thus significantly improving the light emitting efficiency.

Implementation two: Implementation two is basically same as implementation one except the following. The stress releasing layer only includes the first stress releasing layer 30 and does not include the second stress releasing layer 40, the third stress releasing layer 50, and the fourth stress releasing layer 60. The N-type GaN layer 70 is formed on the first stress releasing layer 30.

In the implementation, as for the structure, the manufacture condition, the growth thickness, and the advantageous effect of the first stress releasing layer 30, reference can be made to implementation one, which will not be repeated herein.

Implementation three: Implementation three is basically same as implementation one except the following. The stress releasing layer only includes the first stress releasing layer 30 and the third stress releasing layer 50 and does not include the second stress releasing layer 40 and the fourth stress releasing layer 60. The third stress releasing layer 50 is directly formed on the first stress releasing layer 30. The N-type GaN layer 70 is formed on the third stress releasing layer 50.

In the implementation, as for the structure, the manufacture condition, the growth thickness, and the advantageous effect of the first stress releasing layer 30 and the third stress releasing layer 50, reference can be made to implementation one, which will not be repeated herein.

Implementation four: Implementation four is basically same as implementation one except the following. The stress releasing layer only includes the first stress releasing layer 30, the second stress releasing layer 40, and the fourth stress releasing layer 60 and does not include the third stress releasing layer 50. The N-type GaN layer 70 is formed on the fourth stress releasing layer 60.

In the implementation, as for the structure, the manufacture condition, the growth thickness, and the advantageous effect of the first stress releasing layer 30, the second stress releasing layer 40, and the fourth stress releasing layer 60, reference can be made to implementation one, which will not be repeated herein.

A light emitting device is further provided in implementations of the disclosure. The light emitting device includes the epitaxial structure in the foregoing implementations. The light emitting device in the implementation may be a micro-LED chip. On the one hand, excessive tensile stress caused by lattice mismatch and thermal mismatch between a large-size substrate 10 and the epitaxial structure is alleviated, a problem of a crack of the epitaxial structure grown on the large-size substrate 10, especially a silicon substrate 10, is solved, thereby improving crystal quality, also improving uniformity of the micro-LED caused by stress under the large-size substrate 10 after the stress is effectively controlled, and correspondingly reducing color difference caused by inconsistent emission wavelengths of a micro-LED chip. On the other hand, the QCSE caused by piezoelectric polarization in a multi-quantum light emitting layer can be reduced, thereby realizing efficient combination of electrons and holes in the quantum well, and thus significantly improving light emitting efficiency.

It is to be understood that the disclosure is not to be limited to the disclosed implementations. Those of ordinary skill in the art can make improvements or changes based on the above description, and all these improvements and changes should fall within the protection scope of the appended claims of this disclosure.

What is claimed is:

1. An epitaxial structure, comprising:
a substrate;
a buffer layer formed on the substrate; and
a stress releasing layer, the stress releasing layer comprising a stress releasing layer A formed on the buffer layer, and the stress releasing layer A being made of aluminum gallium nitride (AlGaN) in which Al component accounts for 50%-90%.

2. The epitaxial structure of claim 1, wherein the stress releasing layer A has a thickness within 50-150 nanometers (nm).

3. The epitaxial structure of claim 1, wherein the stress releasing layer further comprises a stress releasing layer B formed on the stress releasing layer A and a stress releasing layer D formed on the stress releasing layer B, wherein
the stress releasing layer B is made of aluminum nitride (AlN) and has a quality ratio of group V (N) element to group III (Al) element (V/III ratio) of 400-1000; and
the stress releasing layer D is made of AlN and has a V/III ratio of 30-100.

4. The epitaxial structure of claim 3, wherein the stress releasing layer B has a thickness within 50-100 nm.

5. The epitaxial structure of claim 3, wherein the stress releasing layer D has a thickness within 20-50 nm.

6. The epitaxial structure of claim 1, wherein
the stress releasing layer further comprises a stress releasing layer C formed on the stress releasing layer A; and
the stress releasing layer C is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, and the second sub-stress releasing layer is made of gallium nitride (GaN).

7. The epitaxial structure of claim 6, wherein the first sub-stress releasing layer in the stress releasing layer C has a thickness less than 10 nm, and the second sub-stress releasing layer in the stress releasing layer C has a thickness within 15-30 nm.

8. The epitaxial structure of claim 1, wherein the stress releasing layer further comprises a stress releasing layer B formed on the stress releasing layer A, a stress releasing layer C formed on the stress releasing layer B, and a stress releasing layer D formed on the stress releasing layer C, wherein
the stress releasing layer B is made of AlN and has a V/III ratio of 400-1000;
the stress releasing layer C is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, the second sub-stress releasing layer is made of GaN; and
the stress releasing layer D is made of AlN and has a V/III ratio of 30-100.

9. The epitaxial structure of claim 8 wherein the stress releasing layer B has a thickness within 50-100 nm.

10. The epitaxial structure of claim 8, wherein the first sub-stress releasing layer in the stress releasing layer C has a thickness less than 10 nm, and the second sub-stress releasing layer in the stress releasing layer C has a thickness within 15-30 nm.

11. The epitaxial structure of claim 8, wherein the stress releasing layer D has a thickness within 20-50 nm.

12. The epitaxial structure of claim 1, wherein the epitaxial structure further comprises an N-type GaN layer, a multi-quantum well (MQW) light emitting layer, and a P-type GaN layer that are sequentially formed on the stress releasing layer.

13. A light emitting device, wherein the light emitting device comprises an epitaxial structure, comprising:
a substrate;
a buffer layer formed on the substrate; and
a stress releasing layer, the stress releasing layer comprising a stress releasing layer A formed on the buffer layer, and the stress releasing layer A being made of aluminum gallium nitride (AlGaN) in which Al component accounts for 50%-90%.

14. A method for epitaxial structure manufacture, comprising:
forming a buffer layer on a substrate; and
forming a stress releasing layer on the buffer layer, the stress releasing layer comprising a stress releasing layer A formed on the buffer layer, and the stress releasing layer A being made of aluminum gallium nitride (AlGaN) in which Al component accounts for 50%-90%.

15. The method for epitaxial structure manufacture of claim 14, wherein the stress releasing layer A is formed under a condition that a temperature is greater than 1000° C. and a pressure is less than 75 millibar (mbar), and the stress releasing layer A has a thickness within 50-150 nanometers (nm).

16. The method for epitaxial structure manufacture of claim 14, wherein the stress releasing layer further comprises a stress releasing layer B and a stress releasing layer D, and the method further comprises:
forming the stress releasing layer B on the stress releasing layer A, and forming the stress releasing layer D on the stress releasing layer B, wherein
the stress releasing layer B is made of aluminum nitride (AlN) and has a quality ratio of group V (N) element to group III (Al) element (V/III ratio) of 400-1000; and
the stress releasing layer D is made of AlN and has a V/III ratio of 30-100.

17. The method of claim 14, wherein the stress releasing layer further comprises a stress releasing layer C, and the method further comprises:
forming the stress releasing layer C on the stress releasing layer A, wherein
the stress releasing layer C is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, and the second sub-stress releasing layer is made of gallium nitride (GaN).

18. The method for epitaxial structure manufacture of claim 14, wherein the stress releasing layer further comprises a stress releasing layer B, a stress releasing layer C, and a stress releasing layer D, and the method further comprises:
forming the stress releasing layer B on the stress releasing layer A, forming the stress releasing layer C on the stress releasing layer B, and forming the stress releasing layer D on the stress releasing layer C, wherein
the stress releasing layer B is made of AlN and has a V/III ratio of 400-1000;
the stress releasing layer C is a super-lattice structure formed by alternate growth of a first sub-stress releasing layer and a second sub-stress releasing layer, with the growth of the first sub-stress releasing layer as a start and an alternate growth period not greater than 100, the first sub-stress releasing layer is made of AlN, and the second sub-stress releasing layer is made of GaN; and
the fourth is made of AlN and has a V/III ratio of 30-100.

19. The method for epitaxial structure manufacture of claim 18,
wherein the stress releasing layer B is formed under a condition that a temperature is greater than 1050° C. and a pressure is less than 75 mbar, and the stress releasing layer B has a thickness within 50-100 nm;
wherein the stress releasing layer C is formed under a condition that a temperature is greater than 1000° C. and a pressure is less than 200 mbar; and the first sub-stress releasing layer in the stress releasing layer C has a thickness less than 10 nm, and the second sub-stress releasing layer in the stress releasing layer C has a thickness within 15-30 nm;
wherein the stress releasing layer D is formed under a condition that a temperature is greater than 1050° C. and a pressure is less than 75 mbar, and the stress releasing layer D has a thickness within 20-50 nm.

20. The method for epitaxial structure manufacture of claim 14, further comprising:
forming sequentially on the stress releasing layer an N-type GaN layer, a multi-quantum well (MQW) light emitting layer, and a P-type GaN layer.
